(19) United States
(12) Patent Application Publication
(10) Pub. No.: US 2025/0336750 A1
(43) Pub. Date: Oct. 30, 2025

(54) SEMICONDUCTOR PACKAGE

(71) Applicant: Samsung Electronics Co., Ltd., Suwon-si (KR)

(72) Inventors: Minwoo Cho, Suwon-si (KR); Sounguk Kim, Suwon-si (KR); Hyunggil Baek, Suwon-si (KR)

(21) Appl. No.: 18/940,588

(22) Filed: Nov. 7, 2024

(30) Foreign Application Priority Data
Apr. 26, 2024 (KR) 10-2024-0055955

(51) Int. Cl. H01L 23/367; H01L 23/00; H01L 23/31; H01L 23/373; H01L 23/498; H01L 25/16

(52) U.S. Cl. CPC H01L 23/367; H01L 23/3128; H01L 23/3135; H01L 23/3736; H01L 23/49816; H01L 24/40; H01L 25/16; H01L 24/16; H01L 24/32; H01L 24/37; H01L 24/48; H01L 24/73; H01L 2224/16148; H01L 2224/16227; H01L 2224/32145; H01L 2224/32225; H01L 2224/37124; H01L 2224/37139; H01L 2224/37144; H01L 2224/37147; H01L 2224/3716; H01L 2224/40225; H01L 2224/404; H01L 2224/48227; H01L 2224/73204; H01L 2224/73213; H01L 2224/73255; H01L 2224/73263; H01L 2225/06513; H01L 2225/06517; H01L 2225/06541; H01L 2225/06589; H01L 2924/182

(57) ABSTRACT

A semiconductor package includes a substrate including an interconnection, a semiconductor chip disposed on the substrate and including chip pads and at least one hot spot, a lower heat transfer material layer on at least one side of the semiconductor chip and extending in a first direction, an upper heat transfer material layer on the semiconductor chip and vertically overlapping the at least one hot spot, a heat transfer conductor including a base portion on the lower heat transfer material and a connection portion extending in a second direction, a molded layer covering the semiconductor chip and the heat transfer conductor, and external connection bumps below the substrate. A first area of the base portion of the heat transfer conductor in contact with the lower heat transfer material is equal to or greater than a second area of the connection portion in contact with the upper heat transfer material.

### CROSS-REFERENCE TO RELATED APPLICATION(S)

This application claims benefit of priority to Korean Patent Application No. 10-2024-0055955 filed on Apr. 26, 2024 in the Korean Intellectual Property Office, the disclosure of which is incorporated herein by reference in its entirety.

### BACKGROUND

The present inventive concept relates to a semiconductor package.

With reductions in weight and improvements in performance in electronic devices, the development of semiconductor chips with a high degree of integration has been necessitated. As semiconductor chips are reduced in size and have a higher degree of integration, heat density may increase, and hot spots, formed locally, may cause degradation in the performance of the semiconductor chips. Accordingly, there is demand for semiconductor package technology capable of effectively dissipating heat generated by semiconductor chips.

### SUMMARY

An aspect of the present inventive concept provides semiconductor package having improved heat dissipation properties and a simplified manufacturing process.

According to an aspect of the present inventive concept, there is provided a semiconductor package including a substrate including plural interconnections, a semiconductor chip disposed on the substrate, the semiconductor chip including chip pads electrically connected to corresponding ones of the interconnections, and at least one hot spot, a lower heat transfer material layer disposed on the substrate and adjacent to at least one side of the semiconductor chip, the lower heat transfer material layer extending in a first direction along the substrate, an upper heat transfer material layer disposed on the semiconductor chip, the upper heat transfer material layer vertically overlapping the at least one hot spot, a heat transfer conductor including a base portion on the lower heat transfer material layer, and a connection portion extending from the base portion in a second direction, intersecting the first direction, the connection portion in contact with the upper heat transfer material layer, a molded layer covering each of the semiconductor chip and the heat transfer conductor, and external connection bumps disposed below the substrate, the external connection bumps electrically connected to the interconnection. A first planar area of the base portion of the heat transfer conductor in contact with the lower heat transfer material layer may be equal to or greater than a second planar area of the connection portion of the heat transfer conductor in contact with the upper heat transfer material layer.

According to another aspect of the present inventive concept, there is provided a semiconductor package including a substrate including an interconnection, a semiconductor chip disposed on the substrate, the semiconductor chip electrically connected to the interconnection, a heat transfer conductor disposed around the semiconductor chip, the heat transfer conductor extending onto an upper surface of the semiconductor chip, an upper heat transfer material layer partially connecting the heat transfer conductor and the upper surface of the semiconductor chip to each other, a molded layer covering each of the semiconductor chip and the heat transfer conductor, and external connection bumps disposed below the substrate, the external connection bumps electrically connected to the interconnection. In plan view, the upper heat transfer material layer may protrude toward at least one side of the heat transfer conductor.

According to another aspect of the present inventive concept, there is provided a semiconductor package including a substrate, a semiconductor chip disposed on the substrate, the semiconductor chip including at least one hot spot, a lower heat transfer material layer disposed on the substrate, an upper heat transfer material layer disposed on the at least one hot spot of the semiconductor chip, a heat transfer conductor including a base portion in contact with the lower heat transfer material layer, and a connection portion extending from the base portion, the connection portion in contact with the upper heat transfer material layer, and a molded layer covering each of the semiconductor chip and the heat transfer conductor. In plan view, the base portion may extend from one side of the semiconductor chip in a first direction, and the connection portion may extend from the base portion to the upper heat transfer material layer in a second direction, intersecting the first direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view of a semiconductor package according to an example embodiment, and FIG. 1B is a cross-sectional view taken along line I-I′ of FIG. 1A;

FIGS. 2A to 2E are plan views of semiconductor packages according to example modifications;

FIGS. 3A and 3B are cross-sectional views of semiconductor packages according to example embodiments;

FIG. 4 is a cross-sectional view of a semiconductor package according to an example embodiment;

FIG. 5 is a cross-sectional view of a semiconductor package according to an example embodiment;

FIG. 6 is a cross-sectional view of a semiconductor package according to an example embodiment; and

FIGS. 7A to 7D are diagrams of a process of manufacturing a semiconductor package according to an example embodiment.

### DETAILED DESCRIPTION

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and should be understood not to be constrained to a particular direction in which a device should actually be arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

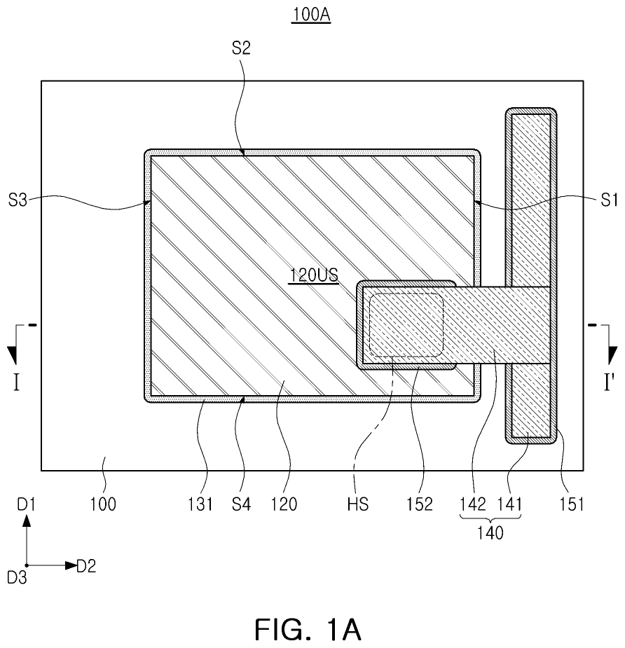

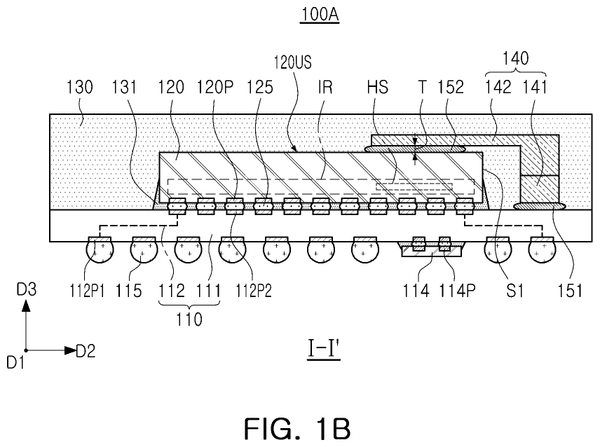

FIG. 1A is a plan view of a semiconductor package 100A according to an example embodiment, and FIG. 1B is a cross-sectional view taken along line I-I′ of FIG. 1A. FIG. 1A illustrates arrangements of components excluding the molded layer 130 in FIG. 1B.

Referring to FIGS. 1A and 1B, the semiconductor package 100A according to an example embodiment may include a substrate 110, a semiconductor chip 120 (or “chip structure”), a molded layer 130, a heat transfer structure 140, and lower and upper heat transfer material layers 151 and 152, respectively. The heat transfer structure 140 may also be referred to as a heat transfer conduit, a heat transfer channel, a heat transfer medium, a heat conductor, or a heat transfer conductor. Note that such terms refer to the thermal conductivity of the heat transfer structure 140, not to electrical conductivity (although the heat transfer structure 140 may or may not also be electrically conductive). In some example embodiments, the semiconductor package 100A may further include external connection bumps 160.

The substrate 110 may be a support substrate on which the semiconductor chip 120 and the heat transfer structure 140 are mounted, and may include an insulating layer 111 and an interconnection 112. The substrate 110 may be a semiconductor package substrate including a printed circuit board (PCB), a ceramic substrate, a glass substrate, or a tape interconnection substrate. For example, the substrate 110 may have a planar shape such as a square, a rectangle, or the like, but the present inventive concept is not limited thereto. In some example embodiments, the substrate 110 may further include a solder resist layer covering a lower pad 112P1 and an upper pad 112P2.

The insulating layer 111 may include an insulating resin electrically and physically protecting the interconnection 112, for example, a thermosetting resin such as an epoxy resin, a thermoplastic resin such as polyimide, or a prepreg, an Ajinomoto build-up film (ABF), or frame retardant 4 (FR4) including an inorganic filler and/or a glass fiber (or glass cloth or glass fabric). In some example embodiments, the insulating layer 111 may include a photosensitive resin such as a photoImageable dielectric (PID).

The interconnection 112 may extend from the inside of the insulating layer 111 to electrically connect the lower pad 112P1 and the upper pad 112P2 to each other. The interconnection 112 may include a conductive pattern and a conductive via forming an electrical connection path. The interconnection 112 may include at least one metal or an alloy of two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe).

The external connection bumps 115 may be disposed below the substrate 110. The external connection bumps 115 may electrically connect the semiconductor package 100A to an external device such as a module substrate, a main board, or the like. The external connection bumps 115 may include a solder ball and/or a conductive filler. The external connection bumps 115 may have, for example, a flip-chip connection structure having a grid array such as a pin grid array, ball grid array, or a land grid array. The external connection bumps 115 may be electrically connected to the interconnection 112 of the substrate 110 through the lower pad 112P1 of the substrate 110. In some example embodiments, a passive component 114 may be mounted on a lower portion of the substrate 110. A terminal 114P of the passive component 114 may be electrically connected to the lower pad 112P1 of the substrate 110. The passive component 114 may improve signal integrity (SI) and/or power integrity (PI) properties of a semiconductor package. The passive component 114 may include, for example, a capacitor, an inductor, a bead, or the like. In some example embodiments, the passive component 114 may be disposed on the inside and/or an upper surface of the substrate 110.

The semiconductor chip 120 (or “chip structure”) may be disposed on the substrate 110, and may be electrically connected to the interconnection 112 of the substrate 110 through connection bumps 125. The connection bumps 125 may electrically connect a chip pad 120P of the semiconductor chip 120 and an upper pad 112P2 of the substrate 110 to each other. The chip pads 120P may be electrical terminals of the semiconductor chip 120 to communicate signals (e.g., data, address and control information) and power between an integrated circuit (IC) of the semiconductor chip 120 and external devices. In some examples, the chip pads 120P may be located on an opposite side of semiconductor chip 120 from the upper heat transfer material layer 152. The connection bumps 125 may include tin (Sn), indium (In), bismuth (Bi), antimony (Sb), copper (Cu), silver (Ag), zinc (Zn), lead (Pb), and/or alloys thereof (for example, Sn—Ag—Cu). In some example embodiments, the connection bumps 125 may be micro-bumps in which a metal pillar and a solder ball are coupled to each other. An underfill layer 131, surrounding the connection bumps 125, may be disposed between the semiconductor chip 120 and the substrate 110. The underfill layer 131 may include an insulating material such as an epoxy resin. The underfill layer 131 may have a capillary underfill (CUF) structure, but the present inventive concept is not limited thereto. The underfill layer 131 may have a molded underfill (MUF) structure integrated with the molded layer 130.

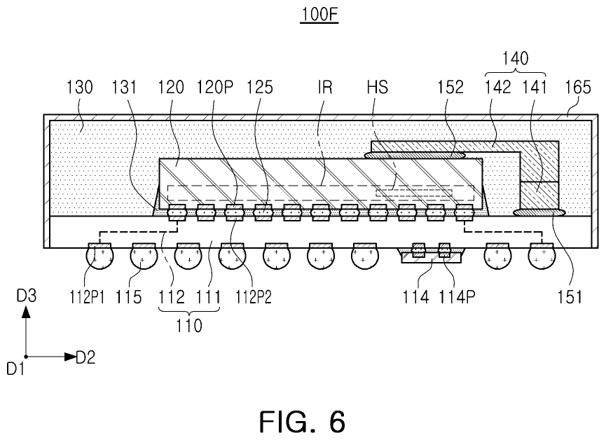

The semiconductor chip 120 may include a portion of a semiconductor wafer and including a semiconductor element such as silicon or germanium, or a compound semiconductor such as silicon carbide (SiC), gallium arsenide (GaAs), indium arsenide (InAs), or indium phosphide (InP). The semiconductor chip 120 may include an integrated circuit formed therein. The semiconductor chip 120 may be a bare semiconductor chip without a bump or an interconnection layer, but the present inventive concept is not limited thereto, and may be a packaged-type semiconductor chip including the bump or the interconnection layer. The semiconductor chip 120 may be a logic circuit (“logic chip”) such as a central processing unit (CPU), a graphics processing unit (GPU), a field programmable gate array (FPGA), an application processor (AP), a digital signal processor, a cryptographic processor, a microprocessor, a microcontroller, an analog-to-digital processor, or an application-specific IC (ASIC), or may be a memory circuit (or ‘memory chip’) including a volatile memory such as dynamic RAM (DRAM) or static RAM (SRAM), and a non-volatile memory such as PRAM, MRAM, RRAM, or flash memory. In some example embodiments, the semiconductor chip 120 may be replaced by a package structure including a plurality of semiconductor chips, which will be described below with reference to FIG. 6.

The semiconductor chip 120 may include a circuit region IR in which an IC is formed and a hot spot HS in the circuit region IR. A hot spot HS may be a localized region in which temperature rapidly rises, as compared to surrounding regions in the circuit region IR, and may not be a region in which highest power is used, but may be understood as a region having a high density of power used relative to an area. Alternatively or additionally, a hot spot HS may be a localized region of semiconductor chip 120 that generates relatively more heat per unit area than other regions, and may not necessarily be hotter than other regions, for example because the hot spot HS may be cooled by the disclosed heat transfer structure 140. The semiconductor chip 120 may include at least one hot spot (HS), which may cause a decrease in performance of the semiconductor chip 120 and a decrease in reliability of the semiconductor package 100A. According to an example embodiment, a heat dissipation path connected to the hot spot HS of the semiconductor chip 120 may be formed by performing a simplified process, using the heat transfer structure 140 and the heat transfer material layers 151 and 152, thereby dissipating heat of the hot spot HS and improving heat dissipation properties and reliability of the semiconductor package 100A.

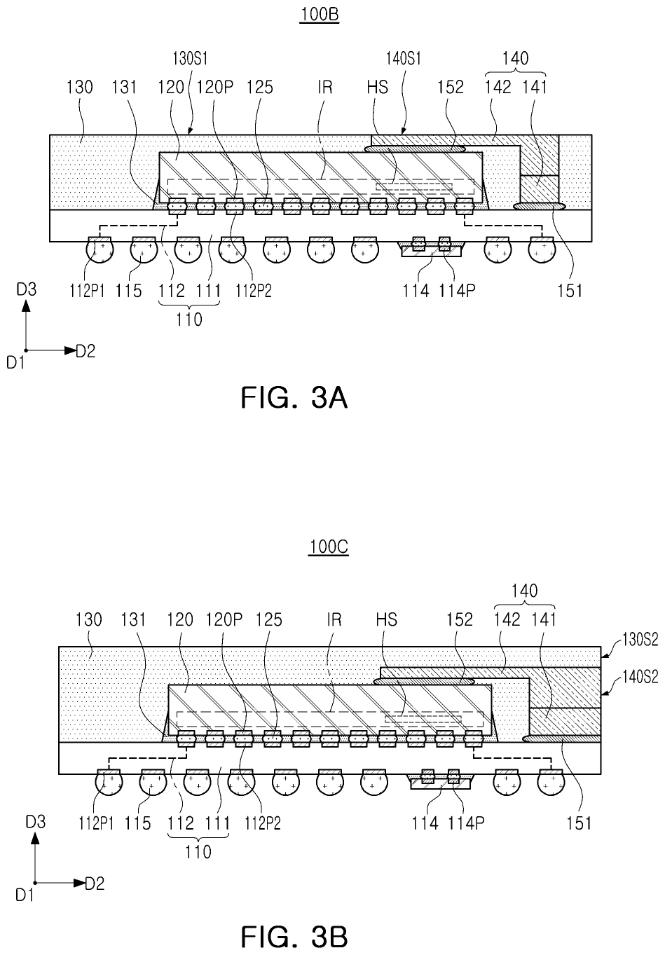

The molded layer 130 may cover each of the semiconductor chip 120 and the heat transfer structure 140. The molded layer 130 may include, for example, a thermosetting resin such as an epoxy resin, a thermoplastic resin such as polyimide, a prepreg, an ABF, FR-4, BT, or an epoxy molding compound (EMC). The molded layer 130 may fill a space between the semiconductor chip 120 and the heat transfer structure 140. In some example embodiments, at least a portion of the heat transfer structure 140 may be exposed from the molded layer 130 (see FIGS. 3A and 3B).

The heat transfer structure 140 may be disposed around the semiconductor chip 120. The heat transfer structure 140 may include at least one of aluminum (Al), gold (Au), silver (Ag), copper (Cu), and iron (Fe), or an alloy thereof. Accordingly, heat transfer structure 140 may have a higher thermal conductivity than the semiconductor chip 120, molded layer 130, and/or substrate 110. Heat transfer structure 140 may be configured to transfer and/or dissipate heat from the hot spot HS without signal or power connections. The heat transfer structure 140 may have a shape extending from the upper surface of the substrate 110 onto an upper surface 120US of the semiconductor chip 120. The heat transfer structure 140 may include a base portion 141 and a connection portion 142.

In some examples, the heat transfer structure 140 is not configured with an electrical signal path, a connection to an integrated circuit within the semiconductor chip 120, and/or a connection to electrical power.

The base portion 141 may extend in at least one direction from one side of the semiconductor chip 120 to ensure structural stability and heat dissipation properties. For example, the base portion 141 may be adjacent to a first side surface S1 of the semiconductor chip 120 extending in a first direction D1, and may extend in a direction, parallel to the first side surface S1. A length of the base portion 141 in the first direction D1 may be greater than a length of the connection portion 142 in the first direction D1.

The connection portion 142 may integrally extend from the base portion 141. The connection portion 142 may extend from the base portion 141 onto the hot spot HS to simplify a manufacturing process and effectively remove heat of the hot spot HS. Accordingly, only a portion of the upper surface 120US of the semiconductor chip 120 may overlap the connection portion 142 in a vertical direction D3. At least a portion of the connection portion 142 may overlap the hot spot HS in the vertical direction D3. For example, as shown in plan view in FIG. 1A, the base portion 141 may extend from one side of the semiconductor chip 120 in the first direction D1, and the connection portion 142 may extend in a second direction D2, intersecting the first direction D1, from the base portion 141 to an upper heat transfer material layer 152 covering the hot spot HS. Accordingly, in some examples, the heat transfer structure 140, base portion 141, and/or connection portion 142 may be asymmetrically positioned or asymmetrically oriented above the semiconductor chip 120 (e.g., when viewed in plan view as in FIG. 1A) so as to overlap the hot spot HS.

The base portion 141 may be in contact with the lower heat transfer material layer 151 to form a heat dissipation region having an area greater than that of the hot spot HS of the semiconductor chip 120, thereby providing greater escape area and capture efficiency for heat dissipation. The connection portion 142 may be in contact with the upper heat transfer material layer 152 to form a heat dissipation path of the hot spot HS. A contact surface between the base portion 141 and the lower heat transfer material layer 151 may be larger than a contact surface between the connection portion 142 and the upper heat transfer material layer 152. For example, a first planar area of the base portion 141 in contact with the lower heat transfer material layer 151 may be equal to or larger than a second planar area of the connection portion 142 in contact with the upper heat transfer material layer 152. Accordingly, the heat transfer structure 140 may be attached to the substrate 110 and the semiconductor chip 120 by performing a simple process such as pressing and/or curing, and may dissipate heat of the hot spot HS.

In some examples, the first planar area of the base portion 141 and the second planar area of the connection portion 142 may be significantly less than a planar area of the semiconductor chip 120, when viewed in plan view as in FIG. 1A. For example, each of the first planar area and the second planar area may be less than 50% of the planar area of semiconductor chip 120. Accordingly, the heat transfer structure 140 can specifically cover hot spot HS. In some examples, the second planar area of the connection portion 142 in contact with the upper heat transfer material layer 152 exceeds an area of the hot spot HS, so as to provide greater escape area and capture efficiency for heat dissipation.

The heat transfer material layers 151 and 152 may include a lower heat transfer material layer 151 and an upper heat transfer material layer 152. The heat transfer material layers 151 and 152 may include a gel, pad, or film-type thermal interface material (TIM). The heat transfer material layers 151 and 152 may include, for example, a thermally conductive adhesive tape, thermally conductive grease, a thermally conductive adhesive, or the like. In some examples, the heat transfer material layers 151 and 152 may be electrically insulating or may not be suitable for conducting electricity. The upper heat transfer material layer 152 may have a predetermined thickness to ensure filling properties of the molded layer 130 (e.g., to allow space for the molded layer 130 to form beneath the connection portion 142). For example, a thickness T of the upper heat transfer material layer 152 may be greater than or substantially equal to 20 μm, but the present inventive concept is not limited thereto. The lower heat transfer material layer 151 may have a thickness the same as or similar to that of the upper heat transfer material layer 152, but the present inventive concept is not limited thereto.

In some examples, the upper heat transfer material layer 152 is configured to transfer heat from the hot spot HS to the heat transfer structure 140, the heat transfer structure 140 is configured to transfer the heat to the lower heat transfer material layer 151, and the lower heat transfer material layer 151 is configured to transfer the heat to the substrate 110 to be dissipated therein.

The lower heat transfer material layer 151 may be disposed between the substrate 110 and the heat transfer structure 140. The lower heat transfer material layer 151 may be in contact with the base portion 141 of the heat transfer structure 140. The lower heat transfer material layer 151 may have a shape corresponding to a planar shape (e.g., a projection in the plan view of FIG. 1A) of the base portion 141. For example, the lower heat transfer material layer 151 may elongate in the first direction DI on the substrate 110. The lower heat transfer material layer 151 may protrude toward the outside of the base portion 141 during a process of the heat transfer structure 140 being attached. In plan view, at least a portion of the lower heat transfer material layer 151 may further protrude than one side surface of the base portion 141. For example, a width of the lower heat transfer material layer 151 in the first direction DI and/or the second direction D2 may respectively be greater than a width of the corresponding base portion 141 in the first direction D1 and/or the second direction D2.

The upper heat transfer material layer 152 may be disposed between the semiconductor chip 120 and the connection portion 142 of the heat transfer structure 140. The upper heat transfer material layer 152 may connect a portion of the upper surface 120US of the semiconductor chip 120, which may include the hot spot HS, to the heat transfer structure 140. The upper heat transfer material layer 152 may allow the upper surface 120US of the semiconductor chip 120 to be partially in contact with the connection portion 142. The upper heat transfer material layer 152 may overlap the hot spot HS with respect to the vertical direction D3 (e.g., may overlap as seen in the plan view of FIG. 1A). The upper heat transfer material layer 152 may partially cover the upper surface 120US of the semiconductor chip 120. The upper heat transfer material layer 152 may be in contact with a first region of the upper surface 120US of the semiconductor chip 120, and the molded layer 130 may be in contact with a second region of the upper surface 120US of the semiconductor chip 120, having an area greater than that of the first region. The upper heat transfer material layer 152 may protrude toward the outside of the connection portion 142 during a process of the heat transfer structure 140 being attached.

In plan view, at least a portion of the upper heat transfer material layer 152 may further protrude than at least one side surface of the connection portion 142, as shown in FIG. 1A. For example, a width of the upper heat transfer material layer 152 in the first direction D1 may be greater than a width of the connection portion 142 in the first direction D1. In some example embodiments, the upper heat transfer material layer 152 may support the connection portion 142 in a region other than the hot spot HS.

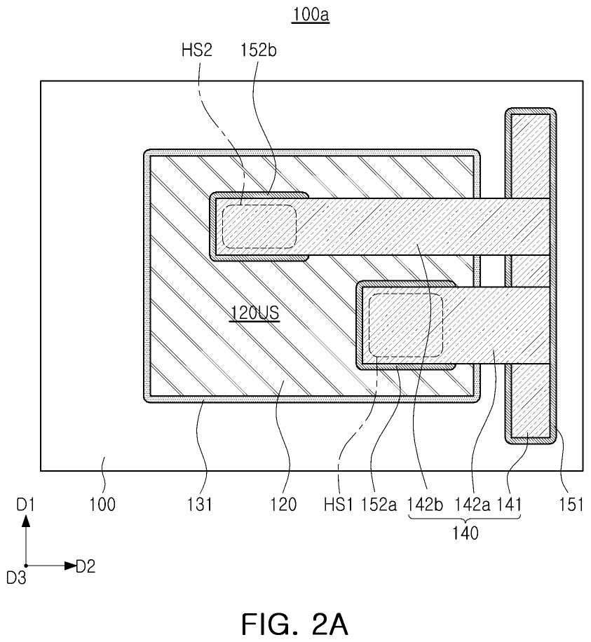

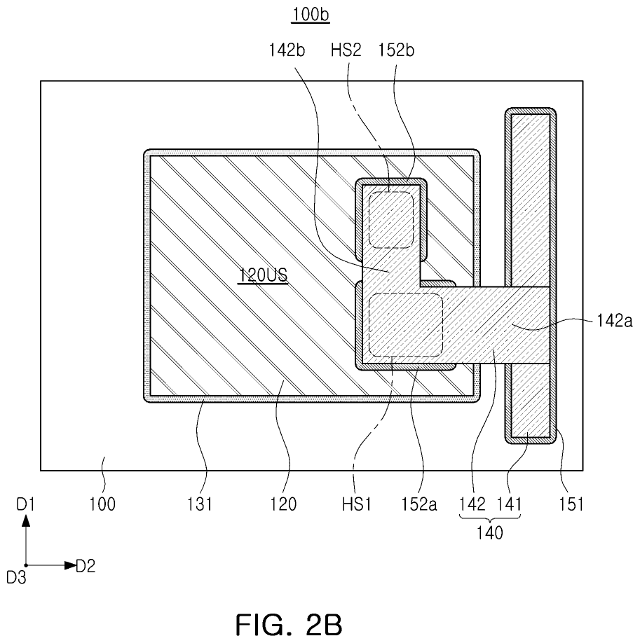

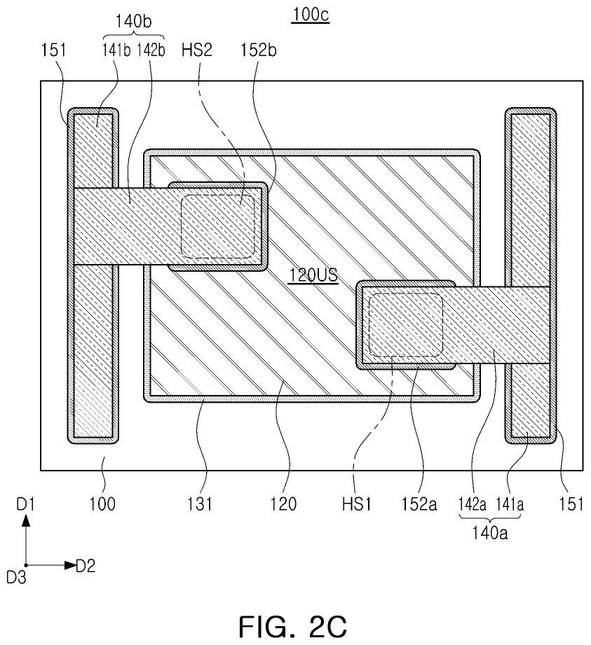

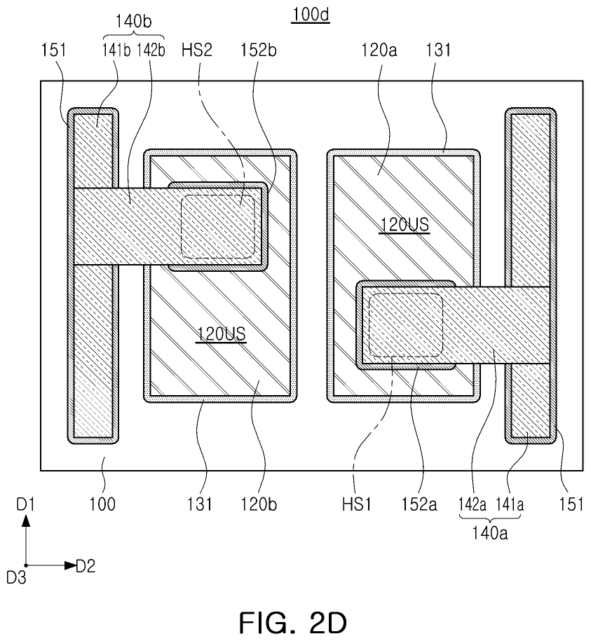

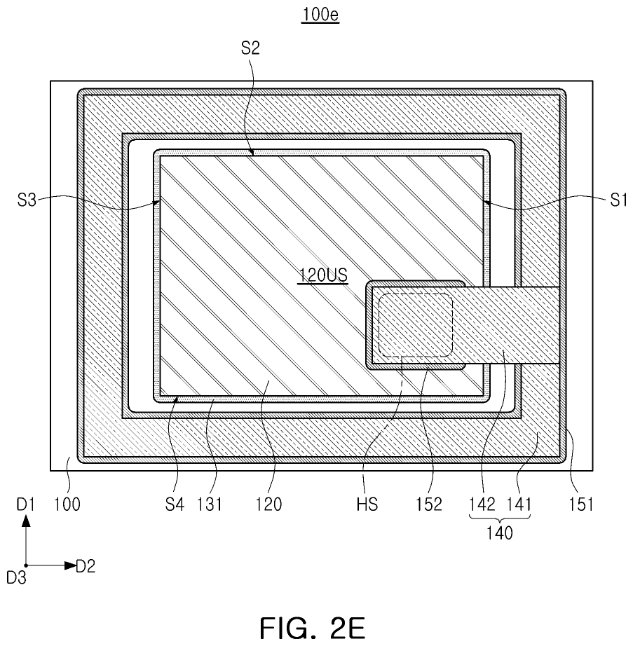

FIGS. 2A to 2E are plan views of semiconductor packages according to example modifications.

Referring to FIG. 2A, a semiconductor package 100a according to an example modification may have features the same as or similar to those described with reference to FIGS. 1A and 1B, except that a heat transfer structure 140 includes a plurality of connection portions 142a and 142b. In an example modification, the heat transfer structure 140 may include connection portions 142a and 142b corresponding to hot spots HS1 and HS2 of a semiconductor chip 120, respectively. For example, the semiconductor chip 120 may include a first hot spot HS1 and a second hot spot HS2, spaced apart from each other, and the heat transfer structure 140 may include a first connection portion 142a extending over the first hot spot HS1, and a second connection portion 142b extending over the second hot spot HS2. In addition, the semiconductor package 100a according to an example modification may include a first upper heat transfer material layer 152a between the first hot spot HS1 and the first connection portion 142a, and a second upper heat transfer material layer 152b between the second hot spot HS2 and the second connection portion 142b. The first connection portion 142a and the second connection portion 142b may be respectively in contact with the first upper heat transfer material layer 152a and the second upper heat transfer material layer 152b to dissipate heat.

Referring to FIG. 2B, a semiconductor package 100b according to an example modification may have features the same as or similar to those described with reference to FIGS. 1A to 2A, except that a heat transfer structure 140 includes a curved connection portion 142 (e.g., having a bend or corner). In an example modification, the heat transfer structure 140 may include a connection portion 142 that is bent to correspond to positions of hot spots HS1 and HS2 of a semiconductor chip 120. For example, the semiconductor chip 120 may include a first hot spot HS1 and a second hot spot HS2, spaced apart from each other, and the connection portion 142 may be bent at least once to pass through both the first hot spot HS1 and the second hot spot HS2. In addition, the semiconductor package 100b according to an example modification may include a first upper heat transfer material layer 152a between the first hot spot HS1 and a first connection portion 142a, and a second upper heat transfer material layer 152b between the second hot spot HS2 and a second connection portion 142b. The connection portion 142 may extend toward a path in contact with both the first upper heat transfer material layer 152a and the second upper heat transfer material layer 152b.

Referring to FIG. 2C, a semiconductor package 100c according to an example modification may have features the same as or similar to those described with reference to FIGS. 1A and 2B, except that a heat transfer structure 140 includes a plurality of heat transfer structures 140a and 140b. In an example modification, the plurality of heat transfer structures 140a and 140b may be provided to correspond to hot spots HS1 and HS2 of a semiconductor chip 120, respectively. For example, the semiconductor chip 120 may include a first hot spot HS1 and a second hot spot HS2, spaced apart from each other, and the plurality of heat transfer structures 140a and 140b may include a first heat transfer structure 140a adjacent to the first hot spot HS1, and a second heat transfer structure 140b adjacent to the second hot spot HS2. The first heat transfer structure 140a and the second heat transfer structure 140b may respectively include a first connection portion 142a extending onto the first hot spot HS1 and a second connection portion 142b extending onto the second hot spot HS2. In addition, the semiconductor package 100c according to an example modification may include a first upper heat transfer material layer 152a between the first hot spot HS1 and the first heat transfer structure 140a, and a second upper heat transfer material layer 152b between the second hot spot HS2 and the second heat transfer structure 140b. The connection portions 142a of the first heat transfer structure 140a and 142b of the second heat transfer structure 140b may be respectively in contact with the corresponding first upper heat transfer material layer 152a and second upper heat transfer material layer 152b to dissipate heat.

Referring to FIG. 2D, a semiconductor package 100d according to an example modification may have features the same as or similar to those described with reference to FIGS. 1A to 2C, except that semiconductor package 100d includes a plurality of semiconductor chips 120a and 120b and a plurality of heat transfer structures 140a and 140b. In an example modification, the plurality of heat transfer structures 140a and 140b may be provided to correspond to the semiconductor chips 120a and 120b, respectively.

For example, a first semiconductor chip 120a including a first hot spot HS1 and a second semiconductor chip 120b including a second hot spot HS2 may be provided, and the plurality of heat transfer structures 140a and 140b may include a first heat transfer structure 140a and a second heat transfer structure 140b respectively adjacent to the first semiconductor chip 120a and the second semiconductor chip 120b. The first heat transfer structure 140a and the second heat transfer structure 140b may respectively include a first connection portion 142a extending onto a first hot spot HS1 and a second connection portion 142b extending onto a second hot spot HS2. In addition, the semiconductor package 100d according to an example modification may include a first upper heat transfer material layer 152a between the first hot spot HS1 of the first semiconductor chip 120a and the first heat transfer structure 140a, and a second upper heat transfer material layer 152b between the second hot spot HS2 of the second semiconductor chip 120b and the second heat transfer structure 140b. The connection portions 142a of the first heat transfer structure 140a and 142b of the second heat transfer structure 140b may be respectively in contact with the corresponding first upper heat transfer material layer 152a and second upper heat transfer material layer 152b to dissipate heat.

Referring to FIG. 2E, a semiconductor package 100e according to an example modification may have features the same as or similar to those described with reference to FIGS. 1A to 2D, except that a heat transfer structure 140 includes a base portion 141 surrounding a semiconductor chip 120. In an example modification, the heat transfer structure 140 may include a base portion 141 bent to continuously surround side surfaces S1, S2, S3, and S4 of the semiconductor chip 120. For example, the base portion 141 may extend in a first direction D1 and a second direction D2 along the side surfaces S1, S2, S3, and S4 of the semiconductor chip 120. A lower heat transfer material layer 151 may extend around the semiconductor chip 120 to correspond to the base portion 141.

In some examples, the heat transfer structure 140 may also include a connection portion 142 extending onto a hot spot HS. In some example embodiments, the base portion 141 may include a plurality of base portions partially surrounding the side surfaces S1, S2, S3, and S4 of the semiconductor chip 120. In this case, at least some base portions, among the plurality of base portions, may include various types of connection portions, such as connection portion 142 of FIG. 2E, and/or as described with reference to FIGS. 2A to 2D.

FIGS. 3A and 3B are cross-sectional views of semiconductor packages 100B and 100C according to example embodiments.

Referring to FIGS. 3A and 3B, the semiconductor package 100B according to an example embodiment may have features the same as or similar to those described with reference to FIGS. 1A to 2E, except that at least a portion of a heat transfer structure 140 is exposed from a molded layer 130. In an example embodiment, a portion of the heat transfer structure 140 may be exposed to the outside of the molded layer 130 using a mold grinding process and/or a sawing process. As illustrated in FIG. 3A, in the semiconductor package 100B according to an example embodiment, an upper surface 140S1 of the heat transfer structure 140 may be exposed from the molded layer 130. The upper surface 140S1 of the heat transfer structure 140 may be coplanar with an upper surface 130S1 of the molded layer 130. Alternatively or additionally, as illustrated in FIG. 3B, a side surface 140S2 of a heat transfer structure 140 of the semiconductor package 100C according to an example embodiment may be exposed from the molded layer 130. The side surface 140S2 of the heat transfer structure 140 may be coplanar with a side surface 130S2 of the molded layer 130. As described, a portion of the heat transfer structure 140 may be exposed from the molded layer 130, thereby further improving heat dissipation properties of the semiconductor packages 100B and 100C.

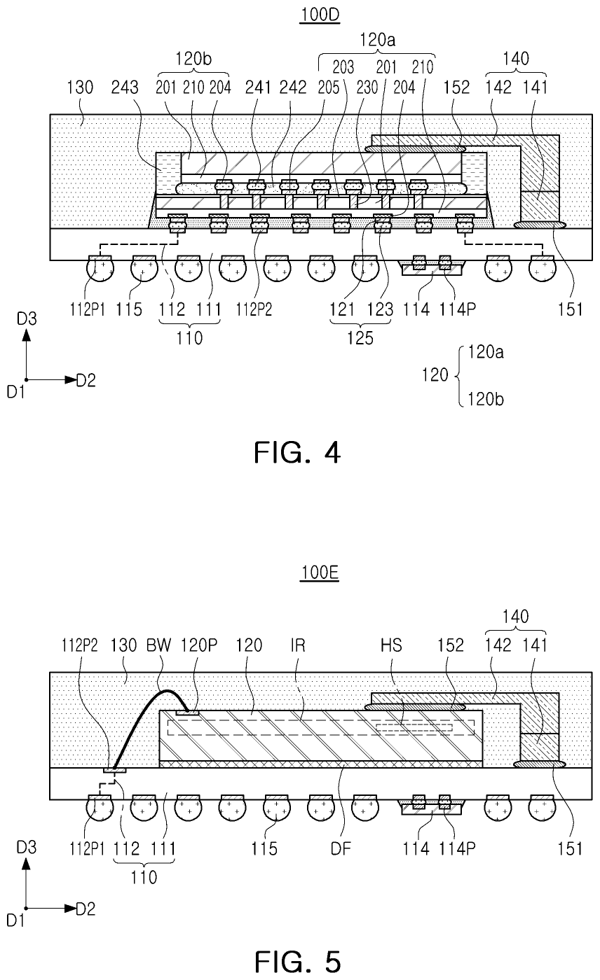

FIG. 4 is a cross-sectional view of a semiconductor package 100D according to an example embodiment.

Referring to FIG. 4, the semiconductor package 100D according to an example embodiment may have features the same as or similar to those described with reference to FIGS. 1A to 3B, except that a chip structure 120 is included in which a plurality of semiconductor chips 120a and 120b are embedded. The plurality of semiconductor chips 120a and 120b may be stacked in a vertical direction D3, and an upper heat transfer material layer 152 may overlap a hot spot of at least one semiconductor chip, among the plurality of semiconductor chips 120a and 120b.

At least some semiconductor chips (for example, “120a”), among the plurality of semiconductor chips 120a and 120b, may include through-vias 230, electrically connecting the plurality of semiconductor chips 120a and 120b to each other. The plurality of semiconductor chips 120a and 120b may be chiplets included in a multi-chip module (MCM). The plurality of semiconductor chips 120a and 120b may include a central processing unit (CPU), a graphics processing unit (GPU), a field programmable gate array (FPGA), a digital signal processor (DSP), a cryptographic processor, a microprocessor, a microcontroller, an analog-to-digital converter, an application-specific integrated circuit (ASIC), a volatile memory, a non-volatile memory, an input/output (I/O) circuit, an analog circuit, a serial-to-parallel conversion circuit, and the like.

In an example embodiment, the chip structure 120 may include a base chip 120a and at least one stacked chip 120b. For example, the base chip 120a may include a processor circuit, and the at least one stacked chip 120b may include at least one of an input/output circuit for the processor circuit, an analog circuit, a memory circuit, and a serial-to-parallel conversion circuit. The base chip 120a and the at least one stacked chip 120b may be provided in number greater than that illustrated in FIG. 4. For example, the at least one stacked chip 120b may include two or more semiconductor chips, horizontally and/or vertically arranged on the base chip 120a.

Each of the base chip 120a and the at least one stacked chip 120b may include a substrate 201, an upper protective layer 203, an upper terminal 205, a circuit layer 210, a lower terminal 204, and/or a through-via 230. The substrate 201 may be formed of, for example, a semiconductor element such as silicon or germanium (Ge), or a compound semiconductor such as silicon carbide (SiC), gallium arsenide (GaAs), indium arsenide (InAs), or indium phosphide (InP). The substrate 201 may have a silicon on insulator (SOI) structure. The substrate 201 may have a conductive region, for example, a well doped with impurities, or an active surface doped with impurities and an inactive surface opposite thereto. Transistors may not be provided with (e.g., formed on and/or within) the inactive surface. In contrast, the active surface may be used to form transistors which may be interconnected to form the integrated circuit of the base chip 120a and the at least one stacked chip 120b. The substrate 201 may include various device isolation structures, such as a shallow trench isolation (STI) structure.

The upper protective layer 203 may be formed on the inactive surface of the substrate 201, and may protect the substrate 201. The upper protective layer 203 may be formed of an insulating layer such as a silicon oxide film, a silicon nitride film, or a silicon oxynitride film, but the material of the upper protective layer 203 is not limited to the above-described materials. Although not illustrated in the drawing, a lower protective layer may be further formed on a lower surface of the circuit layer 210.

The upper terminal 205 may be disposed on the upper protective layer 203. The upper terminal 205 may include, for example, at least one of aluminum (Al), copper (Cu), nickel (Ni), tungsten (W), platinum (Pt), and gold (Au). The lower terminal 204 may be disposed on a lower portion of the circuit layer 210, and may include a material similar to that of the upper terminal 205. However, the materials of the upper terminal 205 and lower terminal 204 are not limited to the above-described materials. The lower terminal 204 of the base chip 120a may be understood as corresponding to the connection terminals 120P described above.

The circuit layer 210 may be provided with the active surface of the substrate 201 (formed on and may also include upper portions of the substrate 201), and may include various types of devices. For example, the circuit layer 210 may include a field effect transistor (FET) such as a planar FET or a FinFET, a memory device such as flash memory, dynamic random access memory (DRAM), static random access memory (SRAM), electrically erasable memory (EEPROM), phase-change random access memory (PRAM), magneto-resistive random access memory (MRAM), ferroelectric random access memory (FeRAM), or resistive random access memory (RRAM), a logic gate such as AND, OR, or NOT, and various active and/or passive devices such as a system large scale integration (LSI), a CMOS imaging sensor (CIS), and a micro-electro-mechanical system (MEMS). The circuit layer 210 may include an interconnection structure (e.g., interconnect layer) electrically connected to the above-described elements, and an interlayer insulating layer surrounding the interconnection structure. The interlayer insulating layer may include silicon oxide or silicon nitride. The interconnect structure may include a multilayer interconnection and/or a vertical contact. The interconnection structure (e.g., interconnect layer) may connect the devices of the circuit layer 210 to each other, may connect the devices to a conductive region of the substrate 201, or may connect the devices to the through-via 230.

The base chip 120a may be disposed below the at least one stacked chip 120b, and may include through-vias 230 electrically connected to the at least one stacked chip 120b. The through-via 230 may pass through the substrate 201 in the vertical direction D3, and may provide an electrical path connecting the upper terminal 205 and the lower terminals 204 to each other. The through-via 230 may include a conductive plug and a barrier film surrounding the conductive plug. The conductive plug may include a metal, such as tungsten (W), titanium (Ti), aluminum (Al), or copper (Cu). The conductive plug may be formed using a plating process, a PVD process, or a CVD process. The barrier film may include an insulating barrier film and/or a conductive barrier film. The insulating barrier film may be formed of an oxide film, a nitride film, a carbonization film, a polymer, or combinations thereof. The conductive barrier film may be disposed between the insulating barrier film and the conductive plug. The conductive barrier film may include a metal compound, for example, tungsten nitride (WN), titanium nitride (TiN), or tantalum nitride (TaN). The barrier film may be formed by a PVD process or a CVD process.

The base chip 120a and the at least one stacked chip 120b may be electrically connected through bumps 241. The bumps 241 may be disposed in an adhesive layer 242 between the base chip 120a and the at least one stacked chip 120b. The bumps 241 may include tin (Sn), indium (In), bismuth (Bi), antimony (Sb), copper (Cu), silver (Ag), zinc (Zn), lead (Pb) and/or alloys thereof, and may have a combination of a metal pillar and a solder ball in some example embodiments. The adhesive layer 242 may surround each of the bumps 241, and may bond the base chip 120a and the at least one stacked chip 120b to each other. The adhesive layer 242 may be formed using a non-conductive film (NCF), but the present inventive concept is not limited thereto, and may be formed, for example, using any type of insulating film on which a heat compression process is performable. In some example embodiments, the base chip 120a and the at least one stacked chip 120b may be connected to each other by directly bonding and combining the corresponding upper terminal 205 and lower terminal 204 to each other without the bumps 241.

The at least one stacked chip 120b may be sealed by a mold 243. The mold 243 may surround external surfaces of the at least one stacked chip 120b and the adhesive layer 242, on the base chip 120a. The mold 243 may include an insulating material, for example, an EMC.

FIG. 5 is a cross-sectional view of a semiconductor package 100E according to an example embodiment.

Referring to FIG. 5, the semiconductor package 100E according to an example embodiment may have features the same as or similar to those described with reference to FIGS. 1A to 4, except that a semiconductor chip 120 is wire-bonded. In an example embodiment, the semiconductor chip 120 may be mounted on a substrate 110 using a wire-bonding method. The semiconductor chip 120 may be disposed such that an active surface on which chip pads 120P are disposed faces upwardly, and the chip pads 120P may be electrically connected to an upper pad 112P2 of the substrate 110 through a bonding wire BW. The bonding wire BW may include gold (Au), silver (Ag), lead (Pb), aluminum (Al), copper (Cu), or alloys thereof. An adhesive film DF may be disposed between the substrate 110 and the semiconductor chip 120. An upper heat transfer material layer 152 may be in contact with a portion of the active surface of the semiconductor chip 120. In some examples, the chip pads 120P may be located on an opposite side of semiconductor chip 120 from the upper heat transfer material layer 152.

FIG. 6 is a cross-sectional view of a semiconductor package 100F according to an example embodiment.

Referring to FIG. 6, the semiconductor package 100F according to an example embodiment may have features the same as or similar to those described with reference to FIGS. 1A to 5. In addition, an electromagnetic wave shielding layer 165 is further included. The electromagnetic wave shielding layer 165 may cover an external surface of each of a molded layer 130 and a substrate 110. The electromagnetic wave shielding layer 165 may be formed by performing a deposition process such as PVD or CVD. The electromagnetic wave shielding layer 165 may include a conductive material, such as iron (Fe), nickel (Ni), gold (Au), silver (Ag), copper (Cu), and alloys thereof. The electromagnetic wave shielding layer 165 may include at least one conductive thin film. For example, the electromagnetic wave shielding layer 165 may be a three-layer thin film in which a stainless steel (SUS) film, a copper (Cu) film, and a stainless steel (SUS) film are sequentially stacked.

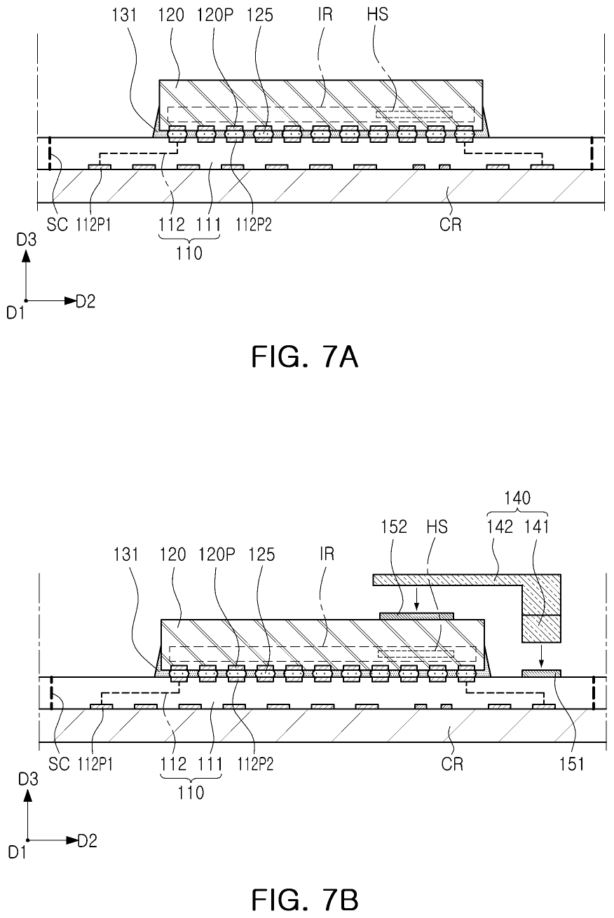

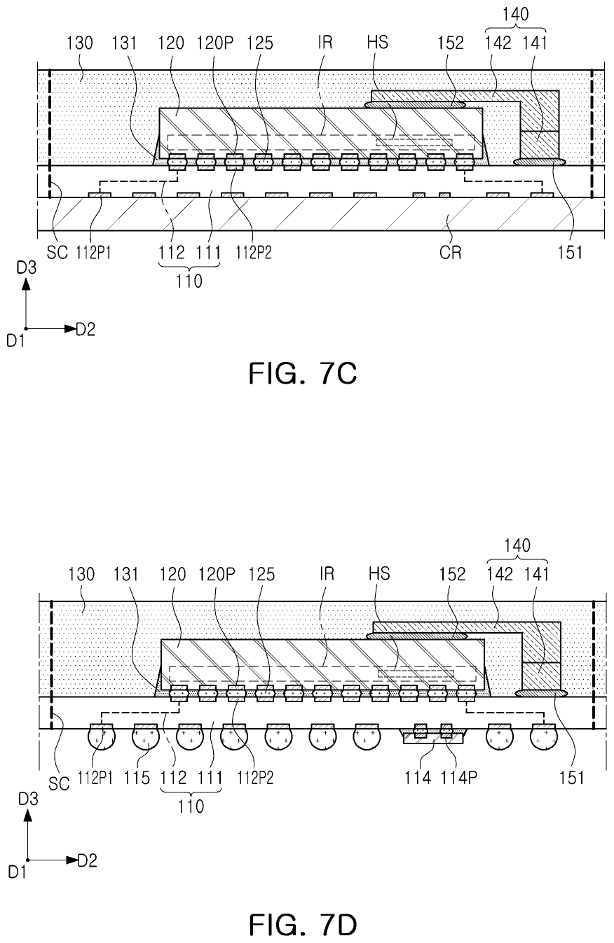

FIGS. 7A to 7D are diagram of a process of manufacturing a semiconductor package according to an example embodiment.

Referring to FIG. 7A, a semiconductor chip 120 may be mounted on a substrate 110. The substrate 110 may be a strip substrate or a wafer substrate including unit substrates 110 divided by a scribe lane SC. The substrate 110 may be temporarily supported by a carrier substrate CR. The carrier substrate CR may be a temporary support including a glass wafer, a curable resin layer, or the like. The semiconductor chip 120 may be connected to upper pads 112P2 of the substrate 110 by connection bumps 125.

Referring to FIG. 7B, a lower heat transfer material layer 151 and an upper heat transfer material layer 152 may be disposed. The lower heat transfer material layer 151 may be disposed on an upper surface of the substrate 110. The lower heat transfer material layer 151 may be disposed around the semiconductor chip 120 in consideration of a size (a width or the like) of a heat transfer structure 140. The upper heat transfer material layer 152 may be locally disposed on an upper surface of the semiconductor chip 120. The upper heat transfer material layer 152 may be disposed in a position overlapping that of a hot spot HS of the semiconductor chip 120. The lower heat transfer material layer 151 and the upper heat transfer material layer 152 may be formed by dispensing or attaching a gel or film-type TIM.

Thereafter, the heat transfer structure 140 may be attached to the lower heat transfer material layer 151 and the upper heat transfer material layer 152. The heat transfer structure 140 may include a base portion 141 and a connection portion 142. The base portion 141 may be in contact with the lower heat transfer material layer 151, and the connection portion 142 may be in contact with the upper heat transfer material layer 152. The heat transfer structure 140 may be attached to the substrate 110 and the semiconductor chip 120 by performing a simple process such as pressing and/or curing, and may dissipate heat of the hot spot HS.

Referring to FIG. 7C, a molded layer 130, covering the semiconductor chip 120 and the heat transfer structure 140, may be formed. The molded layer 130 may be formed by coating and curing a molding material (for example, an EMC) and then performing a planarization process such as a grinding process or a chemical mechanical polishing (CMP) process. In some example embodiments, the molded layer 130 may be planarized to expose an upper surface of the heat transfer structure 140.

Referring to FIG. 7D, after the carrier substrate CR is removed, connection bumps 115 and passive components 114 may be attached to a lower surface of the substrate 110. Thereafter, unit packages may be separated from each other by performing a sawing process along the scribe lane (SC).

According to example embodiments of the present inventive concept, a heat transfer structure, attached to a package substrate using a heat transfer material layer, may be used, such that a semiconductor package may have improved heat dissipation properties and a simplified manufacturing process.

While example embodiments have been shown and described above, it will be apparent to those skilled in the art that modifications and variations could be made without departing from the scope of the present inventive concept as defined by the appended claims.

1. A semiconductor package comprising:
a substrate including plural interconnections;
a semiconductor chip disposed on the substrate, the semiconductor chip including chip pads electrically connected to corresponding ones of the interconnections, and at least one hot spot;
a lower heat transfer material layer disposed on the substrate and adjacent to at least one side of the semiconductor chip, the lower heat transfer material layer extending in a first direction along the substrate;
an upper heat transfer material layer disposed on the semiconductor chip, the upper heat transfer material layer vertically overlapping the at least one hot spot;
a heat transfer conductor including a base portion on the lower heat transfer material layer, and a connection portion extending from the base portion in a second direction, intersecting the first direction, the connection portion in contact with the upper heat transfer material layer;
a molded layer covering each of the semiconductor chip and the heat transfer conductor; and
external connection bumps disposed below the substrate, the external connection bumps electrically connected to the interconnection,
wherein a first planar area of the base portion of the heat transfer conductor in contact with the lower heat transfer material layer is equal to or greater than a second planar area of the connection portion of the heat transfer conductor in contact with the upper heat transfer material layer.

2. The semiconductor package of claim 1, wherein a length of the base portion of the heat transfer conductor in the first direction is greater than a length of the connection portion of the heat transfer conductor in the first direction.

3. The semiconductor package of claim 1, wherein at least a portion of the lower heat transfer material layer further protrudes than one side surface of the base portion of the heat transfer conductor, and
wherein at least a portion of the upper heat transfer material layer further protrudes than one side surface of the connection portion of the heat transfer conductor.

4. The semiconductor package of claim 1, wherein a width of the lower heat transfer material layer in the second direction is greater than a width of the base portion of the heat transfer conductor in the second direction.

5. The semiconductor package of claim 1, wherein a width of the upper heat transfer material layer in the first direction is greater than a width of the connection portion of the heat transfer conductor in the first direction.

6. The semiconductor package of claim 1, wherein a thickness of the upper heat transfer material layer is 20 μm or more.

7. The semiconductor package of claim 1, wherein the upper heat transfer material layer is in contact with a first region of an upper surface of the semiconductor chip,
wherein the molded layer is in contact with a second region of the upper surface of the semiconductor chip, and
wherein an area of the second region is greater than an area of the first region.

8. The semiconductor package of claim 1, wherein the heat transfer conductor includes at least one of aluminum (Al), gold (Au), silver (Ag), copper (Cu), and iron (Fe), or an alloy thereof, and
wherein the lower heat transfer material layer and the upper heat transfer material layer include a gel, a pad, a film, a thermally conductive adhesive tape, a thermally conductive grease, a thermally conductive adhesive, or another thermal interface material (TIM).

9. The semiconductor package of claim 1, wherein the at least one hot spot includes a first hot spot and a second hot spot, spaced apart from each other,
wherein the upper heat transfer material layer includes a first upper heat transfer material layer and a second upper heat transfer material layer corresponding to the first hot spot and the second hot spot, respectively, and
wherein the heat transfer conductor includes a first connection portion and a second connection portion in contact with the first upper heat transfer material layer and the second upper heat transfer material layer, respectively.

10. The semiconductor package of claim 1, wherein the at least one hot spot includes a first hot spot and a second hot spot, spaced apart from each other,
wherein the upper heat transfer material layer includes a first upper heat transfer material layer and a second upper heat transfer material layer corresponding to the first hot spot and the second hot spot, respectively, and
wherein the connection portion of the heat transfer conductor is bent and in contact with both the first upper heat transfer material layer and the second upper heat transfer material layer.

11. The semiconductor package of claim 1, wherein the at least one hot spot includes a first hot spot and a second hot spot, spaced apart from each other,
wherein the upper heat transfer material layer includes a first upper heat transfer material layer and a second upper heat transfer material layer corresponding to the first hot spot and the second hot spot, respectively,
wherein the heat transfer conductor includes a first heat transfer conductor adjacent to the first upper heat transfer material layer, and a second heat transfer conductor adjacent to the second upper heat transfer material layer, and
wherein the first heat transfer conductor and the second heat transfer conductor respectively include a first connection portion in contact with the first upper heat transfer material layer and a second connection portion in contact with the second upper heat transfer material layer.

12. The semiconductor package of claim 1, wherein the semiconductor chip includes a first semiconductor chip and a second semiconductor chip, spaced apart from each other,
wherein the first semiconductor chip includes a first hot spot,
wherein the second semiconductor chip includes a second hot spot,
wherein the upper heat transfer material layer includes a first upper heat transfer material layer and a second upper heat transfer material layer corresponding to the first hot spot and the second hot spot, respectively,
wherein the heat transfer conductor includes a first heat transfer conductor adjacent to the first semiconductor chip, and a second heat transfer conductor adjacent to the second semiconductor chip, and
wherein the first heat transfer conductor and the second heat transfer conductor respectively include a first connection portion in contact with the first upper heat transfer material layer and a second connection portion in contact with the second upper heat transfer material layer.

13. The semiconductor package of claim 1, wherein the lower heat transfer material layer extends around the semiconductor chip in the first direction and the second direction, and
wherein the base portion of the heat transfer conductor extends along the lower heat transfer material layer, and surrounds a side surface of the semiconductor chip.

14. The semiconductor package of claim 1, wherein an upper surface of the heat transfer conductor is exposed from the molded layer.

15. The semiconductor package of claim 1, wherein the semiconductor chip includes a plurality of semiconductor chips stacked in a vertical direction, and
wherein the upper heat transfer material layer overlaps a hot spot of at least one semiconductor chip, among the plurality of semiconductor chips.

16. The semiconductor package of claim 1, wherein the semiconductor chip is disposed such that an active surface on which the chip pads are disposed faces upwardly,
wherein the chip pads are electrically connected to the interconnection through a bonding wire, and
wherein the upper heat transfer material layer is in contact with a portion of the active surface of the semiconductor chip.

17. A semiconductor package comprising:
a substrate including an interconnection;
a semiconductor chip disposed on the substrate, the semiconductor chip electrically connected to the interconnection;
a heat transfer conductor disposed around the semiconductor chip, the heat transfer conductor extending onto an upper surface of the semiconductor chip;
an upper heat transfer material layer partially connecting the heat transfer conductor and the upper surface of the semiconductor chip to each other;
a molded layer covering each of the semiconductor chip and the heat transfer conductor; and
external connection bumps disposed below the substrate, the external connection bumps electrically connected to the interconnection,
wherein, in plan view, the upper heat transfer material layer protrudes toward at least one side of the heat transfer conductor.

18. The semiconductor package of claim 17, further comprising:
a lower heat transfer material layer disposed between the heat transfer conductor and the substrate,
wherein, in plan view, the lower heat transfer material layer protrudes toward at least a second side of the heat transfer conductor.

19. The semiconductor package of claim 17, wherein only a portion of the upper surface of the semiconductor chip overlaps the heat transfer conductor in a vertical direction.

20. A semiconductor package comprising:
a substrate;
a semiconductor chip disposed on the substrate, the semiconductor chip including at least one hot spot;
a lower heat transfer material layer disposed on the substrate;
an upper heat transfer material layer disposed on the at least one hot spot of the semiconductor chip;
a heat transfer conductor including a base portion in contact with the lower heat transfer material layer, and a connection portion in contact with the upper heat transfer material layer; and
a molded layer covering each of the semiconductor chip and the heat transfer conductor,
wherein, in plan view, the base portion extends from one side of the semiconductor chip in a first direction, and
wherein the connection portion extends from the base portion to the upper heat transfer material layer in a second direction, intersecting the first direction.

21-28. (canceled)
